(19) United States
(12) Patent Application Publication
(10) Pub. No.: US 2024/0280636 A1
(43) Pub. Date: Aug. 22, 2024

(54) METHOD FOR MONITORING SHORT CIRCUIT SWITCHING PROCESSES OF A CIRCUIT OF A CONTROL DEVICE

(71) Applicant: Robert Bosch GmbH, Stuttgart (DE)

(72) Inventors: Frank Hettrich, Eberdingen (DE); Andreas Schwaerzle, Stuttgart (DE); Siyun Chu, Ludwigsburg (DE)

(21) Appl. No.: 18/570,336

(22) PCT Filed: Jun. 27, 2022
(86) PCT No.: PCT/EP2022/067559

§ 371 Date: Dec. 14, 2023

(30) Foreign Application Priority Data
Jul. 16, 2021 (DE) 10 2021 207 633.5

(51) Int. Cl. G01R 31/327

(52) U.S. Cl. CPC G01R 31/327

(57) ABSTRACT

A method for monitoring short circuit switching processes of a circuit, in particular an output stage circuit of a control device. Information relating to the control device is acquired and evaluated to determine whether a short circuit switching process has occurred, in the course of which the circuit carries out a switching process during a short circuit. If it is recognized in the course of the evaluation that a short circuit switching process has occurred, a counter reading which characterizes the number of short circuit switching processes carried out over the service life of the circuit is updated.

### FIELD

The present invention relates to a method for monitoring short circuit switching processes of a circuit of a control device, in particular in a vehicle, and a computing unit for carrying out the method.

### BACKGROUND INFORMATION

Output stages or output stage circuits in control devices, for example in (motor) vehicles, represent the last electronic stage of a power amplifier before an amplified signal is applied to a load. Output stage circuits can, for instance, be provided in an engine control device in order to provide the power required to control actuators. In the control device, the respective output stage circuits can be controlled by a microcontroller via appropriate control signals.

In order to be able to ensure the (operational) safety of the control device, the output stage circuits should be built mostly robust enough to be able to withstand at least a specified minimum number of switching (-on) processes in the event of a short circuit, i.e., if there is a short circuit to battery or ground. However, if too many such short circuit switching processes are carried out, in particular with PWM control, the output stage and thus the entire control device can be damaged or even destroyed.

### SUMMARY

A method for monitoring short circuit switching processes of a circuit of a control device and a computing unit for carrying out the method are provided according to the present invention. Advantageous embodiments of the present invention are disclosed herein.

According to an example embodiment of the present invention, in the course of the method, current information relating to the control device is acquired and evaluated to determine whether a short circuit switching process has occurred, i.e., whether the circuit is carrying out a switching-on process during a short circuit (i.e., without load). If it is recognized in the course of the evaluation that a short circuit switching process has occurred, a counter or counter reading which characterizes or represents the number of short circuit switching processes carried out over the service life of the circuit is updated or increased.

Acquiring and evaluating the control device information expediently makes it possible to detect, during ongoing operation of the control device, whether a short circuit switching process is currently occurring. The counter reading is therefore updated continuously throughout the service life when a new short circuit switching process is detected.

According to an example embodiment of the present invention, measures to protect the output stage circuit or to correct errors, for example, can be carried out based on the counter reading. The counter reading also makes it possible to determine how high the risk of damage or destruction of the output stage is, for example. The operation of the output stage can, for instance, also be restricted or influenced if the counter reading is very high and is approaching a specified number of permitted switching (-on) processes in the event of a short circuit, for instance.

The counter reading can conveniently be read out in a workshop and can, for example, simplify troubleshooting or repair. The counter reading can moreover be helpful for a subsequent root cause search in the event of damage or destruction of the output stage or the control device. The counter reading can particularly expediently be used to check whether a warranty claim is justified. For example, the counter reading can be used to check whether an (end) customer has ignored a warning, such as an activated check engine light, for an extended period of time, which can lead to a reduction or exclusion of warranty service by the (control device) manufacturer.

According to an example embodiment of the present invention, the information relating to the control device in particular characterizes the current operation of the control device, in particular current signals from the control device for controlling the output stage circuit, in particular also current errors or error messages from the control device. This information particularly expediently makes it possible to determine whether the circuit is currently being controlled and whether there is currently a short circuit in the control device. Different measures for short circuit detection in output stages of vehicle control units are available, for example, and in part also prescribed. Acquired measured values can be evaluated, for example. It is possible to check whether a current through the output stage circuit exceeds a permissible limit value, for example. Error diagnoses or diagnostic functions of the control device can furthermore be used to detect error states, for example.

According to an example embodiment of the present invention, a prioritization of short circuit switching processes that are carried out or should or may be carried out during a specified diagnostic interval, in particular during a current diagnostic interval, is advantageously carried out as a function of the counter reading or a current value of the counter reading. These individual diagnostic intervals can, for instance, respectively correspond to a driving cycle of the (motor) vehicle. Short circuit switching processes that are carried out in the course of an error diagnosis or error detection are expediently prioritized. Such switching processes for error diagnosis can in particular be used to check or detect whether the short circuit is still occurring or whether the control device is functioning correctly again without a short circuit after healing. This prioritization can expediently be used to set or specify how often per diagnostic interval a check whether the short circuit is still occurring is carried out. The higher the assigned priority, the more frequently per diagnostic interval an error diagnosis is carried out. In particular, therefore, as the lifetime of the circuit increases, the number of error diagnoses carried out per diagnostic interval can continuously be reduced in order to avoid an unnecessarily large number of short circuit switching processes and damage or destruction of the output stage circuit.

According to an example embodiment of the present invention, when the counter reading is low, for example, which in particular reflects the beginning of the service life of the output stage, error diagnosis or error detection can be given a higher priority than when the counter reading is higher during a later phase of the output stage's service life, because the chances of healing or correction of the short circuit is greater at the beginning of the service life than toward the end of the service life. For example, by assigning a high priority when the counter reading is low, a check whether the short circuit is still occurring can be carried out several times per diagnostic interval. When the counter reading is higher, a lower assigned priority in particular makes it possible to permit fewer or no switching processes for error diagnosis per diagnostic interval in order to avoid unnecessary loads or even a failure in the output stage circuit. For instance, a switching process can be assigned a high or highest priority for error diagnosis if the counter reading is below a specified limit value. The closer the counter reading gets to this limit value, the lower the selected priority can be.

The number of short circuit switching processes carried out per diagnostic interval is traditionally limited to a fixed maximum number, for example depending on a type of the respective output stage, a voltage supply, a system being used, a configuration, sensors being used, a current ambient temperature, etc. Usually, when a short circuit is detected, an error message is issued, in particular by activating a check engine light, and, at fixed intervals during a diagnostic interval, further switching-on processes, up to the fixed maximum number of short circuit switching processes per diagnostic interval, are used to check whether the short circuit is still occurring. If the short circuit has not been resolved by then, a corresponding function of the control device is often permanently deactivated across-the-board for the remainder of the diagnostic interval. Even if the short circuit is healed in this diagnostic interval, it is no longer possible to detect this and the corresponding function nonetheless remains deactivated. A check of the short circuit may only be carried out again in a following diagnostic interval.

In contrast, in the method according to an example embodiment of the present invention, the counter reading can be used to dynamically adjust how often a check for errors is carried out per diagnostic interval, in particular based on the lifetime. Since healing is more likely at the beginning of the lifetime than with a long lifetime, checks are carried out more frequently here, so that any healing of the short circuit can be detected and control device functions are not unnecessarily deactivated across-the-board even though a short circuit may no longer be occurring. With a long lifetime, it is then only possible to check for errors rarely or not at all per diagnostic interval, because healing is less likely, but the risk of destruction of the output stage circuit is increased.

According to an example embodiment of the present invention, a number of short circuit switching processes that are carried out or should or may be carried out during a diagnostic interval or a driving cycle, in particular during a current diagnostic interval or driving cycle, is preferably limited as a function of the counter reading or a current value of the counter reading. As explained above, short circuit switching processes for error diagnosis can often be limited across-the-board to a static, fixed value per diagnostic interval in the conventional manner. In contrast, by introducing the counter reading, the number of permitted short circuit switching processes per diagnostic interval can particularly expediently be limited dynamically over the service life of the circuit, in particular dynamically adapted to the number of short circuit switching processes that the circuit has already carried out during its lifetime thus far.

According to a preferred embodiment of the present invention, the counter reading or the current value of the counter reading is compared with a specified threshold value. This threshold value can be specified as a function of a minimum number of short circuit switching processes that the output stage circuit should at least withstand during its service life, for example. For example, the threshold value can show that the number of short-circuit switching processes that have been carried out thus far is increasingly approaching this minimum number, thus giving rise to an increasing risk of damage to the circuit. When the threshold value is reached or exceeded, further switching-on processes can in particular be prevented or prohibited. The short-circuit switching processes are preferably prioritized and/or the number of short-circuit switching processes is limited as a function of the comparison of the current value of the counter reading with the specified threshold value. There is therefore in particular no across-the-board, static limitation of switching processes per diagnostic interval; instead, it is possible to dynamically adjust which or how many switching processes are permitted in the event of a short circuit, expediently depending on the current lifetime of the output stage circuit.

As explained above, in particular a maximum value for a number of short circuit switching processes that may be carried out during a diagnostic interval can be specified as a threshold value.

According to an example embodiment of the present invention, the threshold value is particularly preferably specified as a function of a number of diagnostic intervals that have been carried out. The threshold value is thus expediently adjusted dynamically as a function of the lifetime of the output stage circuit thus far.

According to an example embodiment of the present invention, the threshold value, in particular for a current diagnostic interval, is advantageously specified as a function of a (e.g., linear or logarithmic) relationship between a number of permitted short circuit switching processes and one of the diagnostic intervals that have been carried out thus far. The use of a logarithmic relationship makes it possible to allow a high number of short circuit switching processes per diagnostic interval, in particular at the beginning of the output stage's service life. As the number approaches a corresponding minimum number of short circuit switching processes that the output stage circuit should at least withstand during its service life, increasingly fewer short circuit switching processes can be permitted per diagnostic interval.

According to an example embodiment of the present invention, the threshold value, in particular for a current diagnostic interval, is expediently specified as a function of a maximum value for a number of short-circuit switching processes that may be carried out during the service life of the circuit, and in particular a distance between a number of short circuit switching processes and the maximum value for a number of short-circuit switching processes that may be carried out during the service life of the circuit. The use of such a relationship makes it possible to allow a high number of short circuit switching processes per diagnostic interval, in particular when the distance from the maximum value is large. As the number approaches the maximum value, increasingly fewer short circuit switching processes are permitted per diagnostic interval in order to protect the circuit.

According to an example embodiment of the present invention, the counter reading is preferably increased only if it is recognized in the course of the evaluation that a high-side switch of the circuit is carrying out a switching-on process during a short circuit to ground and/or that a low-side switch of the circuit is carrying out a switching-on process during a short circuit to supply voltage. For output stages installed on the ground side or for low-side switches that are connected to ground with a terminal or in which the load is disposed between the switch and the supply voltage, switch-on pulses can in particular have a damaging effect on the circuit in the event of a short circuit to the supply voltage, so that in this case switching processes during such a short circuit are particularly expediently documented with the counter reading. For voltage-side installed output stages, i.e. for high-side switches that are connected to the supply voltage with a terminal or in which the load is disposed between the switch and ground, on the other hand, switch-on pulses can in particular have a damaging effect on the circuit in the event of short circuits to ground, so that in this case switching processes during ground short circuits are expediently documented by means of the counter reading.

A computing unit according to the present invention, e.g., a control device of a (motor) vehicle, is configured, in particular in terms of programming, to carry out a method according to the present invention.

Further advantages and embodiments of the present invention will emerge from the disclosure herein.

The present invention is illustrated schematically in the figures on the basis of embodiment examples and is described in detail in the following with reference to the figures.

### BRIEF DESCRIPTION OF THE DRAWINGS

FIG. 1 schematically shows a control device with an output stage circuit, which is configured to carry out a preferred embodiment of a method according to the present invention.

FIG. 2 schematically shows a preferred embodiment of a method according to the present invention as a block diagram.

FIG. 3 schematically shows a diagram of a number of permitted short circuit switching processes plotted against a number of driving cycles carried out, which can be determined in the course of a preferred embodiment of a method according to the present invention.

### DETAILED DESCRIPTION OF EXAMPLE EMBODIMENTS

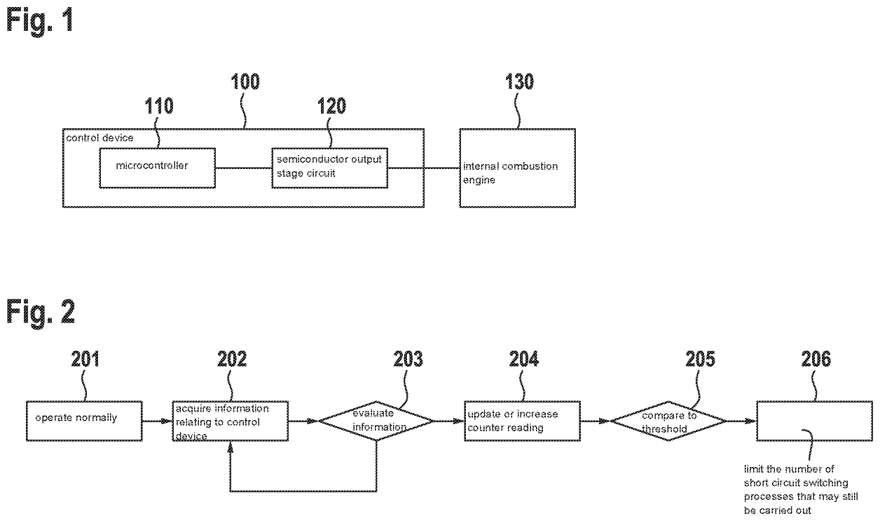

FIG. 1 schematically shows a control device of a (motor) vehicle that is labeled 100.

The control device 100 can be provided as an engine control device for controlling an internal combustion engine 130, for example, and comprises a microcontroller 110 and a semiconductor output stage circuit 120, for example in the form of a MOSFET bridge circuit with high-side switches and/or low-side switches. The microcontroller 110 can control these semiconductor switching elements of the output stage circuit 120 by means of corresponding control pulses.

The output stage 120 is designed to be able to withstand a minimum number of short circuit switching processes without damage. Exceeding this number of short circuit switching processes could result in an increased risk of damage or even destruction to the output stage 120 and the control device 100.

To guard against this hazard, the control device 100 is configured, in particular in terms of programming, to carry out a preferred embodiment of a method according to the present invention, which is shown schematically in FIG. 2 as a block diagram and will be explained in the following.

In a Step 201, the control device 100 or the corresponding (motor) vehicle is operated normally. In Step 202, information relating to the control device 100 is acquired; in particular information that characterizes the current operation of the control device. This information in particular relates to current signals or control pulses of the microcontroller 110 for controlling the output stage circuit 120 as well as current present errors of the control device 100. This information includes a duty cycle of a control signal of semiconductor switching elements, currents through semiconductor switching elements, error memory information or inputs into an error memory, for example.

In a Step 203, this information is evaluated to determine whether a short circuit switching process has occurred i.e. whether a control pulse or a switch (-on) pulse is being output to the output stage circuit 120 by the microcontroller 110 while an error state in the form of a short circuit is occurring in the output stage circuit 120; in particular whether a high-side switch of the output stage circuit 120 is thus carrying out a switching-on process to ground and/or whether a low-side switch is carrying out a switching-on process to supply voltage (e.g. battery).

As long as this is not the case and no such short circuit switching process is occurring, the information relating to the control device continues to be acquired in Step 202 and evaluated in Step 203.

However, if it is recognized in Step 203 that such a short circuit switching process is occurring, a counter reading which characterizes the number of short circuit switching processes carried out over the service life of the output stage circuit 120 is updated or increased in Step 204. The current value of this counter reading thus corresponds to the number of all short circuit switching processes that the output stage circuit 120 has carried out since the beginning of its service life or since it was first put in operation in the control device 100.

This counter reading can be read in a workshop, for example, and used for troubleshooting, repair or checking a warranty claim. For example, the counter reading can be used to check whether a driver of the vehicle has ignored a warning, e.g. an activated check engine light, for an extended period of time, which can lead to a reduction or exclusion of warranty service by the manufacturer of the control device 100.

In Step 205, the counter reading or the current value of the counter reading is compared with a threshold value, in particular with a maximum value for the number of short circuit switching processes that may be carried out during a diagnostic interval or a driving cycle for error diagnosis.

The number of permitted short circuit switching processes per diagnostic interval is often statically limited to a constant fixed value in the conventional manner. The introduction of the present counter reading, on the other hand, makes it possible to flexibly and dynamically adjust the permitted short-circuit switching operations per diagnostic interval as a function of the number of short circuit switching processes that the circuit 120 has already carried out during its lifetime thus far.

The threshold value is in particular specified as a function of a number of diagnostic intervals that the output stage circuit 120 or the vehicle has already carried out. In the early phases at the beginning of the service life of the output stage circuit 120, a higher number of short-circuit switching processes per diagnostic interval can be permitted than in later phases, for instance, because there is a greater chance of the short circuit being healed at the beginning of the service life. The threshold value for the current diagnostic interval is in particular specified as a function of a linear or logarithmic relationship between the number of permitted short circuit switching processes and the number of diagnostic intervals that have been carried out.

In Step 206, the number of short circuit switching processes that may still be carried out in the current diagnostic interval for error diagnosis is limited based on the threshold value comparison 205. A prioritization of individual short circuit switching processes on the basis of the comparison result can be carried out in Step 206 as well. At the beginning of the service life of the circuit 120, for instance, short circuit switching processes can be assigned a higher or highest priority in the course of the error diagnosis, and a high or even unlimited number of such switching processes can be permitted per diagnostic interval for error diagnosis because, in this case, there is a high chance of healing or successful error resolution. In later phases of the service life after a high number of diagnostic intervals that have been carried out, the priority of such short circuit switching processes for error diagnosis can be selected to be lower, for example, and only one attempt or one switching process for error diagnosis can be specified, for instance, in order to avoid possible damage or destruction of the control device 100.

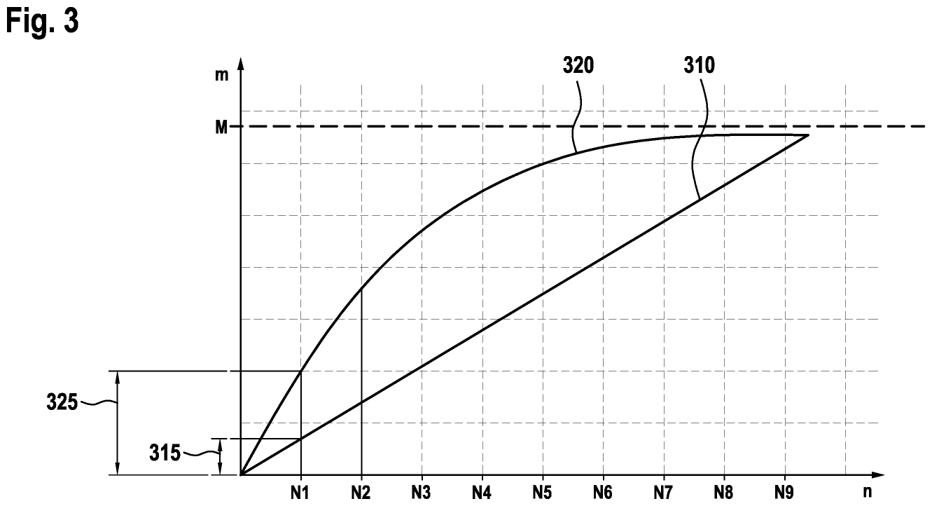

FIG. 3 schematically shows a diagram of the number m of permitted short circuit switching processes plotted against the number n of diagnostic intervals that have been carried out.

The curve 310 represents a corresponding linear relationship and the curve 320 represents a corresponding logarithmic relationship, as a function of which the threshold value for the current diagnostic interval can be specified in Step 205.

M refers to a minimum number of short circuit switching processes that the output stage circuit 120 should at least withstand during its service life.

315 refers to the number of permitted short circuit switching processes for the diagnostic interval N1 in accordance with the linear relationship 310, for example, and 325 refers to the number of permitted short circuit switching processes for the diagnostic interval N1 in accordance with the logarithmic relationship 320.

In particular at the beginning of the service life of the circuit 120, more short circuit switching processes are permitted per diagnostic interval in accordance with the logarithmic relationship 320 than in accordance with the linear relationship 310. Also, fewer and fewer short-circuit switching processes are permitted per diagnostic interval in accordance with the logarithmic relationship 320 as the number approaches the minimum number M.

The number of permitted short circuit switching processes per diagnostic interval can be ascertained online during the current diagnostic interval on the basis of the logarithmic relationship 320 using a Taylor expansion, for instance.

A qualitatively similar curve is obtained when the threshold value is specified as a function of a distance between a number of short circuit switching processes and the maximum value for a number of short-circuit switching processes that may be carried out during the service life of the circuit. This makes it possible to permit a high number of short circuit switching processes per diagnostic interval, in particular when the distance from the maximum value is large. As the number approaches the maximum value, increasingly fewer short circuit switching processes are permitted per diagnostic interval in order to protect the circuit.

1-10. (canceled)

11. A method for monitoring short circuit switching processes of an output stage circuit of a control device, the method comprising the following steps:
acquiring information relating to the control device;
evaluating the acquired information to determine whether a short circuit switching process has occurred, wherein the output stage circuit carries out a switching-on process during a short circuit; and
updating, when it is recognized based on the evaluation that a short circuit switching process has occurred, a counter reading which characterizes a number of short circuit switching processes carried out over a service life of the output stage circuit.

12. The method according to claim 11, further comprising:
carrying out a prioritization or limitation of short circuit switching processes carried out during a diagnostic interval, including short circuit switching processes carried out in the course of an error diagnosis, as a function of the counter reading.

13. The method according to claim 11, wherein the counter reading is compared with a specified threshold value, the specified threshold value being a specified maximum value for a number of short circuit switching processes that may be carried out during a diagnostic interval.

14. The method according to claim 13, wherein the specified threshold value is specified as a function of a number of diagnostic intervals.

15. The method according to claim 14, wherein the specified threshold value is specified as a function of a relationship between the number of short circuit switching processes and the number of diagnostic intervals.

16. The method according to claim 13, wherein the specified threshold value is specified as a function of a maximum value for a number of short circuit switching processes that may be carried out during the service life of the circuit.

17. The method according to claim 16, wherein the specified threshold value is specified as a function of a distance between the number of short circuit switching processes and the maximum value for a number of short circuit switching processes that may be carried out during the service life of the circuit.

18. The method according to claim 13, wherein the short circuit switching processes are prioritized and/or the number of short circuit switching processes is limited as a function of the comparison.

19. The method according to claim 11, wherein the counter reading is updated when it is recognized in the course of the evaluation that a high-side switch of the output stage circuit is carrying out a switching-on process during a short circuit to ground and/or that a low-side switch of the output stage circuit is carrying out a switching-on process during a short circuit to battery.

20. A computing unit configured to monitor short circuit switching processes of an output stage circuit of a control device, the computing unit configured to:
acquire information relating to the control device;
evaluate the acquired information to determine whether a short circuit switching process has occurred, wherein the output stage circuit carries out a switching-on process during a short circuit; and
update, when it is recognized based on the evaluation that a short circuit switching process has occurred, a counter reading which characterizes a number of short circuit switching processes carried out over a service life of the output stage circuit.
